(19) United States
(12) Patent Application Publication
(10) Pub. No.: US 2006/0098764 A1
(43) Pub. Date: May 11, 2006

(54) Method of protecting a frequency of a data stream from interference and circuit performing such a method

(75) Inventor: Jozef Reinerus Maria Bergervoet, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Phillips Electronics N.V., BA Eindhoven (NL)

(21) Appl. No.: 10/529,688

(22) PCT Filed: Aug. 13, 2003
(86) PCT No.: PCT/IB03/03618

§ 371 Date: Mar. 29, 2005

(30) Foreign Application Priority Data
Oct. 2, 2002 (EP) 02079095.2

(51) Int. Cl. H03D 1/04

(52) U.S. Cl. 375/346

(57) ABSTRACT

A method for mixed analog digital designs protecting the frequencies that are important for the analog part. The generated digital data stream has relatively large signal levels compared to the sensitive analog parts. The data bit stream is monitored and their frequency spectrum is corrected. The monitoring is performed by a conversion receiver that is adapted to sample the spectrum in a protected band and to generate an I and Q signal. A correction signal is obtained by multiplying the I and Q signal by the protected frequency. The spectrum is corrected by using the correction signal to generate small shifts in the edges of the data bit stream.

The invention relates to mixed digital analog ICs, to any electronic system processing both digital and analog information and to channel coding/modulation schemes for communication. It particularly relates to the protection of a certain frequency band of interest from interference.

There are many systems which create an interference spectrum containing discrete frequencies. Several systems improve this by changing the discrete frequencies into a continuous spectrum with a lower overall amplitude. This is done, for instance, by deliberately introducing jitter or frequency modulation.

When the device using the system for generating a continuous spectrum as described is trying to receive a signal at a certain frequency and at the same time when creating the interference, the frequency that needs protection will be disturbed.

This interference may be the crosstalk from relatively large digital signal levels to sensitive analog parts in mixed analog digital designs. To some extent, this is avoided by choosing digital clock frequencies that are least harmful for the analog part. Unfortunately, however, the digital data will not only contain multiples of the clock frequency. For more or less random data, it contains an additional continuous frequency spectrum, see R. C. Frye, “Integration and electrical isolation in CMOS mixed-signal wireless chips”, Proceedings of the IEEE, Vol. 89, No. 7, pp. 444-455, April 2001.

Therefore, it is an object of the invention to provide a method of correcting a digital data signal in order to avoid the generation of interference in a certain frequency band. The data stream transports information that is present in the form of bits and is typically a square wave signal. It is another object to provide a circuit adapted to perform the inventive method.

Regarding the method, the object is solved by a method of correcting a digital data signal in order to avoid the generation of interference in a certain frequency band, created by a data stream that is being generated, the method comprising the steps of:

monitoring the generated data bit stream,

analyzing the spectrum, and

correcting the spectrum without changing the digital content.

Analyzing the spectrum may be performed in according with the Fourier Transform. By correcting the spectrum in an adequate manner, it is possible to create a hole in the continuous spectrum. The hole is created around a protected frequency, for example the frequency of a radio channel to be received. This situation will typically arise in a mixed analog digital design, for instance, when the analog part is trying to receive a radio channel.

Regarding the circuit, the object is solved by a circuit adapted to perform a method of correcting a digital data signal in order to avoid the generation of interference in a certain frequency band of a data stream in a mixed analog digital design, the data stream transporting information that is present in the bits, characterized by a loop comprising:

a detector whose output is a measure of the accumulated disturbance in the protected frequency band,

an edge modulator whose input consists of the digital data, with the output of the detector added to it.

According to one embodiment of the inventive method, the generated data bit stream is monitored by a detector adapted to sample the spectrum in the protected band, and generate an I and Q signal.

The direct conversion receiver may consist of two multipliers that sample the spectrum in the protected band and generate an I and Q signal.

Subsequently, the I and Q signal is multiplied by another frequency to obtain a correction signal. This further frequency may either be a different one that is not used in the circuit to avoid further disturbance or again the protected frequency that is easy to obtain in the circuit. A time shift of the edges of the data stream is obtained by adding the correction signal to the input of a comparator.

In one embodiment, the spectrum is corrected by introducing a time shift of each new switching edge. These time shifts are slight and too small to cause problems in the digital domain. The time shifts of the edges of the data stream are obtained by adding the correction signal to the input of a comparator.

The input of data stream is typically a square-wave signal with the two levels “high” and “low”, “high” corresponding to “a bit” and “low” corresponding to “not a bit”. The invention is based on the recognition that, according to the Fourier Transform, the spectrum of a digital signal is a continuous function with an abundant amount of frequencies. The invention is also based on the recognition that deleting one frequency or a small frequency band from the square-wave signal results in a time shift of the edges but does not have any influence on whether a square wave appears or not. This means that the shifts do not influence the content of the data stream if they are chosen prudently.

Subsequently, the output of the comparator is added to the input of the conversion receiver where it is mixed with the input, i.e. the data stream. Leading back the output of the comparator closes the loop of monitoring the generated output data bit stream and correcting its frequency spectrum.

The inventive method can work as long as the repetition of the switching moments, i.e. the bit rate, is much faster than the width of the frequency band that is to be protected. The reason is that the system can thus correct the spectrum on a time-scale that is shorter than the group delay in the receiver of the protected band or frequency. The receiver will then always see the accumulated signal of many switching edges, and it is precisely the accumulated interference of many switching edges that the invention will minimize.

These and other aspects of the invention are apparent from and will be elucidated with reference to the embodiments described hereinafter, wherein

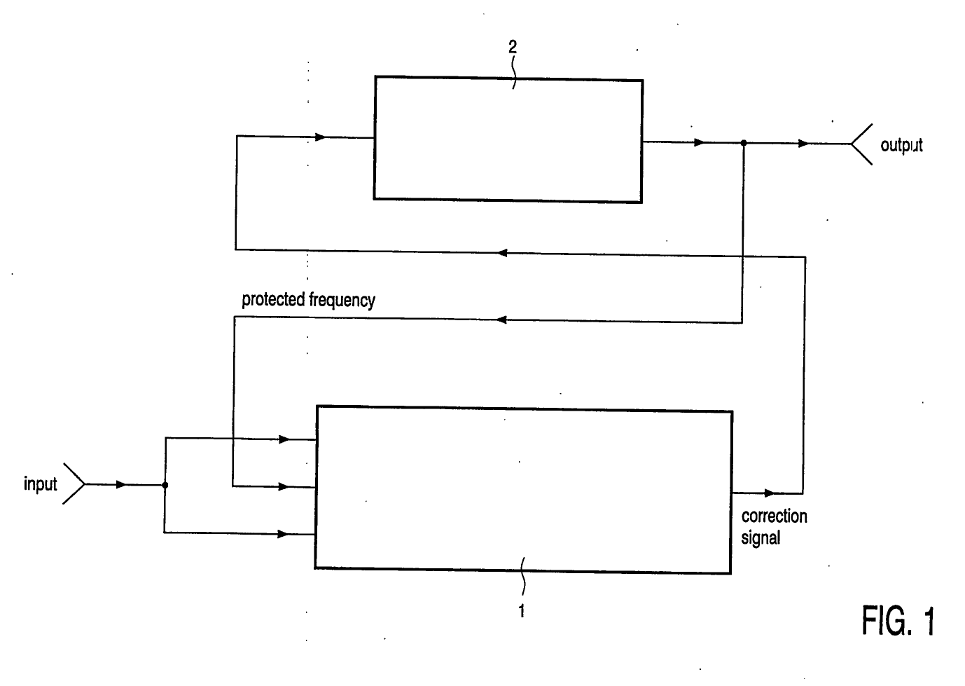

FIG. 1 is a block diagram with the basic elements of the inventive circuit,

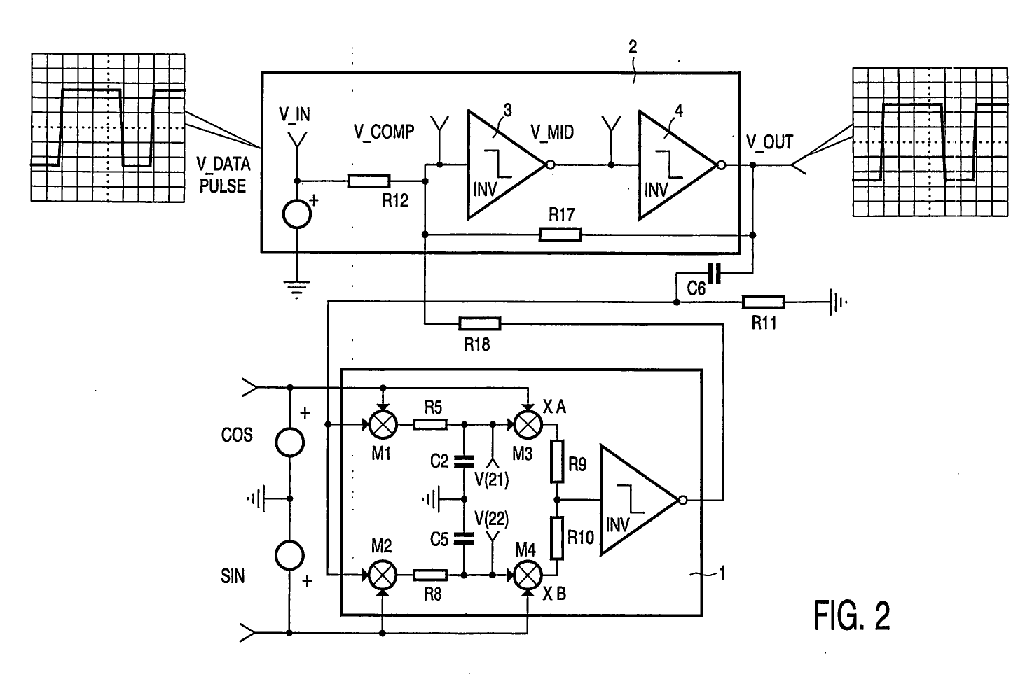

FIG. 2 shows one implementation of a circuit adapted to perform the method,

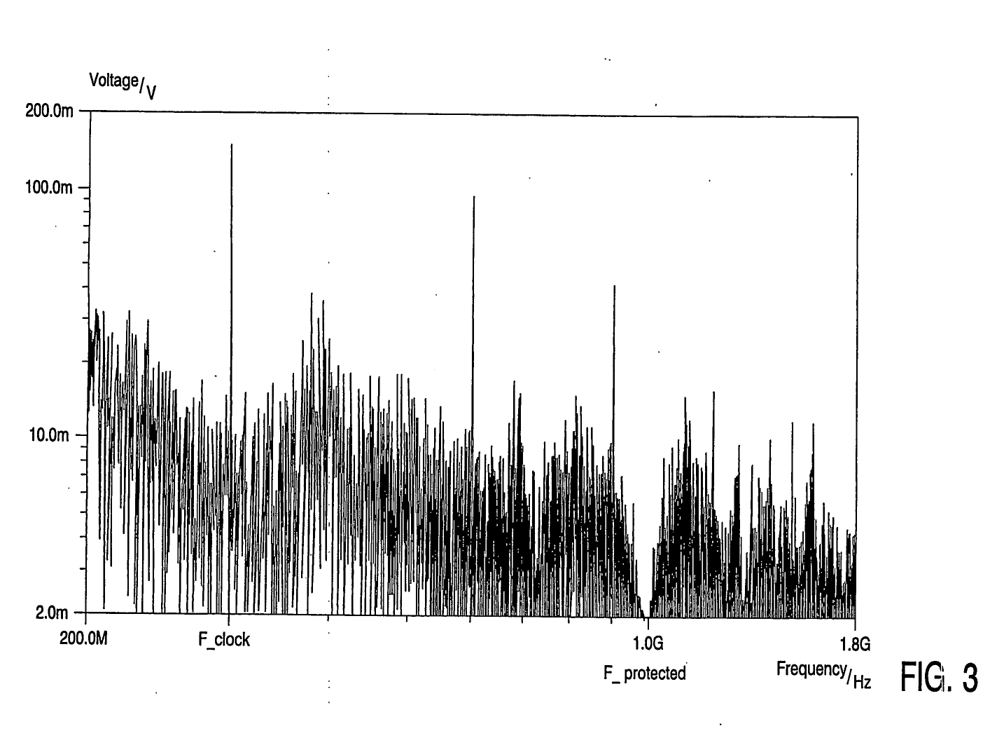

FIG. 3 shows one example of a resulting spectrum for random bits as input.

FIG. 1 is a block diagram with the basic elements of the inventive circuit for a mixed analog digital design. The input signal is an analog data stream, for example, a radio channel with a center frequency, the output is a digital signal that has a continuous spectrum with a hole around the protected frequency. The basic elements are a detector 1 of the disturbance in the protected band, which detects the spectral content, and an edge modulator 2 comprising a digital data source. The edge correcting signal is generated by the detector 1 depending on the spectral content of its input signal. The output of the detector 1 is the edge correction input signal for the edge modulator 2. The generated output data of the edge modulator 2 is also led back to the input of detector 1.

FIG. 2 shows one implementation of a circuit adapted to perform the inventive method. FIG. 2 shows a circuit that consists substantially of two parts: one part concerning the edge modulator 2 comprising essentially two comparators 3, 4 that perform the edge modulation and another part containing a direct-conversion receiver that functions as the detector 1, for monitoring the protected frequency band. The protected frequency band is, for example, the frequency band of a communication channel that is being received. The protected frequency enters the detector 1 as a quadrature signal with sine and cosine components. The data signal to be monitored enters via a capacitor C6. The detector 1 comprising, among other components, two multipliers M1, M2 and the resistors and capacitors R5, C2, R8 and C5 monitors the spectral content of the data signal in the protected frequency band. The I and Q components of the spectral content are integrated by the components R5, C2, R8 and C5. Afterwards, they are multiplied again by the protected frequency by a second set of two multipliers M3, M4 in order to create the correction signal for the edges. This correction signal is fed back to the digital data channel via resistor R18 and is combined with the digital input data, V_in, to create the input, V_comp, for a comparator.

The comparator of the edge modulator 2 of the described embodiment consists substantially of two inverters 3, 4 in a series arrangement and a resistor parallel to the inverters. The implementation shown in FIG. 2 presents one possibility. A completely digital version is possible as well.

FIG. 3 shows a resulting spectrum for random bits as input The spectrum contains:

peaks at harmonics of the clock frequency,

a noise-like background associated with random data, and

a hole around the protected frequency.

It becomes obvious that the spectrum contains more frequencies than the multiples of the clock frequency. As the square-wave signal comprises an abundant amount of frequencies, the background is noise-like. In this example, the clock frequency is 300 MHz and the protected frequency is 1.0 GHz. The hole around it in the frequency spectrum indicates the strong reduction of interference at the protected frequency.

In summuray, the invention relates to a method for mixed analog digital designs protecting the frequencies that are important for the analog part. The generated digital data stream has relatively large signal levels compared to the sensitive analog parts. The data bit stream is monitored and their frequency spectrum is corrected. The monitoring can be performed by a conversion receiver that is adapted to sample the spectrum in a protected band and to generate an I and Q signal. A correction signal is obtained by multiplying the I and Q signal by the protected frequency. The spectrum can be corrected by using the correction signal so as to generate a small shift in the edges of the data bit stream.

The invention also relates to a circuit for performing a method of correcting a digital data stream in order to protect a certain frequency, comprising a loop that is built by an edge modulator, for example a conversion receiver, whose output is combined with the input data stream of the circuit at the input of a comparator whose output data stream is again fed back to the input of the conversion receiver.

1. A method of correcting a digital data signal in order to avoid the generation of interference in a certain frequency band, characterized by the steps of:
monitoring the generated data bit stream,
analyzing the spectrum, and
correcting the spectrum without changing the digital content.

2. A method as claimed in claim 1, characterized in that the generated data bit stream is monitored by a detector (1) adapted to
sample the spectrum in the protected band, and
generate an I and Q signal.

3. A method as claimed in claim 2, characterized in that a correction signal is obtained by multiplying the I and Q signal again by another frequency.

4. A method as claimed in claim 3, characterized in that the correction signal is obtained by multiplying the I and Q signal by the protected frequency.

5. A method as claimed in claim 3, characterized in that a time shift of the edges of the data stream is obtained by adding the correction signal to the input of a comparator.

6. A method as claimed in claim 5, characterized in that the output of the comparator is added to the input of the detector (1).

7. A circuit adapted to perform a method of correcting a digital data signal in order to avoid the generation of interference in a certain frequency band of a data stream, the data stream transporting information that is present in the bits, characterized by a loop comprising:
a detector (1) whose output is a measure of the accumulated disturbance in the protected frequency band,
an edge modulator (2) whose input consists of the digital data, with the output of the detector added to it.
